(19) United States
(12) Patent Application Publication
(10) Pub. No.: US 2021/0360798 A1
(43) Pub. Date: Nov. 18, 2021

(54) Printed Circuit Board and Vehicle Having the Same

(71) Applicants: Hyundai Motor Company, Seoul (KR); Kia Motors Corporation, Seoul (KR); Hyundai KEFICO Corporation, Gunpo-si (KR)

(72) Inventors: SeungWoo Choi, Seoul (KR); Seong-Rae Cho, Incheon (KR); Seoung-Won Kim, Seoul (KR); Hyeok-Jin Jeong, Seoul (KR)

(21) Appl. No.: 17/180,173

(22) Filed: Feb. 19, 2021

(30) Foreign Application Priority Data
May 14, 2020 (KR) 10-2020-0057780

(51) Int. Cl. H05K 3/46; H05K 1/09

(52) U.S. Cl. CPC H05K 3/4658; H05K 1/09; H05K 2201/0355; H05K 3/4691; H05K 3/4635

(57) ABSTRACT

A printed circuit board includes a rigid part including a central insulating layer for insulation, inner copper foil layers including a first conductive circuit portion, outer insulating layers for insulation, and outer copper foil layers including a second conductive circuit portion, wherein ones of the inner copper foil layers, the outer insulating layers, and the outer copper foil layers are symmetrically positioned on opposite sides of the central insulating layer and are sequentially laminated, and a flexible part formed by selectively removing a portion of the rigid part up to one side of the central insulating layer.

### CROSS-REFERENCE TO RELATED APPLICATIONS

This application claims the benefit of Korean Patent Application No. 10-2020-0057780, filed on May 14, 2020, in the Korean Intellectual Property Office, which application is hereby incorporated herein by reference.

### TECHNICAL FIELD

The disclosure relates to a printed circuit board and a vehicle including the same.

### BACKGROUND

In general, a flexible part that may be bent is coupled to a printed circuit board having a rigid part, which is advantageous in providing an interface with excellent chipset mounting properties and flexibility.

In order to form such a conventional flexible part, a printed circuit board may be configured such that flexible parts are further laminated and connected, or may be configured such that a flexible part that may be bent is laminated together on a rigid part and then a portion of the laminated rigid part is selectively removed to have flexibility by the flexible part that has not been removed.

However, because a conventional printed circuit board on which a flexible part is formed further includes a layer forming the flexible part, the overall laminated structure becomes complex and the thickness thereof becomes thick.

Also, when the overall thickness of a printed circuit board becomes thin, a power failure occurs in a harsh environment in a vehicle where high humidity and vibration occurs due to the flexible part, and reliability and high quality may not be secured.

### SUMMARY

The disclosure relates to a printed circuit board and a vehicle including the same. Particular embodiments relate to a printed circuit board having a laminated structure in which a rigid part and a flexible part are formed and a vehicle including the same.

An embodiment of the disclosure provides a printed circuit board that may be bent and may not experience a power failure even in a laminated structure of a simple and thin rigid part by providing a flexible part capable of being bent to a laminated structure having a rigid part, and a vehicle including the same.

Additional embodiments of the disclosure will be set forth in part in the description which follows and, in part, will be obvious from the description, or may be learned by practice of the disclosure.

In accordance with an embodiment of the disclosure, a printed circuit board and a vehicle including the same include a rigid part configured such that a central insulating layer for insulation, inner copper foil layers including a conductive circuit portion, outer insulating layers for insulation, and outer copper foil layers including a conductive circuit portion, which are symmetrically positioned on opposite sides of the central insulating layer, are sequentially laminated, and a flexible part formed to have flexibility by selectively removing a portion of the rigid part up to one side of the central insulating layer.

A plurality of the outer insulating layers and outer copper foil layers may be sequentially further laminated on outer surfaces of the rigid part.

The inner copper foil layers and the outer copper foil layers may be manufactured by electrolytic plating and rolling with a copper material.

The central insulating layer and the outer insulating layers may include glass fabric and epoxy resin materials.

The outer copper foil layer may be formed to have a thickness of 18 to 35 μm to have flexibility.

The flexible part may be formed to have a width of 9.5 to 10.5 mm to have flexibility.

The inner copper foil layer may be formed to have a thickness of 18 to 70 μm to have flexibility.

The printed circuit board may further include protective layers formed on outer surfaces of the outer copper foil layers.

The protective layer may be formed of a photo shoulder resist (PSR).

### BRIEF DESCRIPTION OF THE DRAWINGS

These and/or other aspects of the disclosure will become apparent and more readily appreciated from the following description of the embodiments, taken in conjunction with the accompanying drawings, in which:

FIG. 1 is a cross-sectional view of a printed circuit board according to an embodiment of the disclosure;

FIG. 2 illustrates that the printed circuit board according to an embodiment of the disclosure is bent; and

FIG. 3 is a cross-sectional view of a printed circuit board according to another embodiment of the disclosure.

### DETAILED DESCRIPTION OF ILLUSTRATIVE EMBODIMENTS

Hereinafter embodiments of the disclosure will be described in detail with reference to the accompanying drawings. The embodiments described below are provided by way of example so that those skilled in the art will be able to fully understand the spirit of the disclosure. The disclosure is not limited to the embodiments described below, but may be embodied in other forms. In order to clearly explain the disclosure, parts not related to the description are omitted from the drawings, and the width, length, thickness, etc. of the components may be exaggerated for convenience. In the drawings, the same reference numerals denote the same components, and redundant descriptions thereof will be omitted.

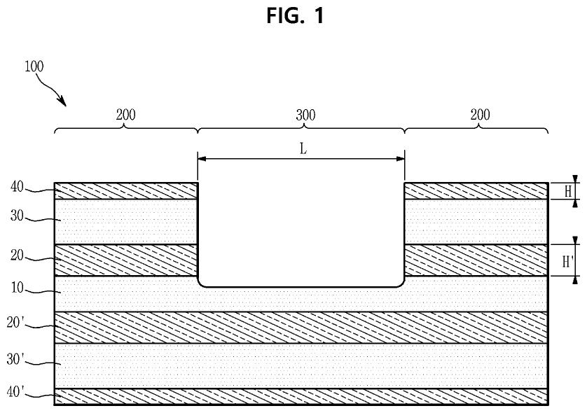

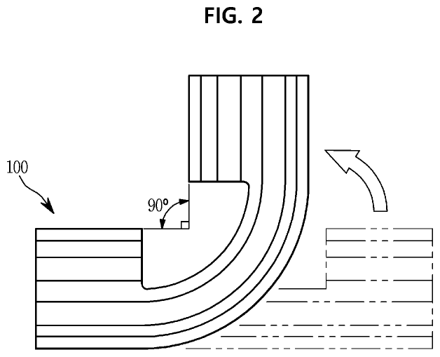

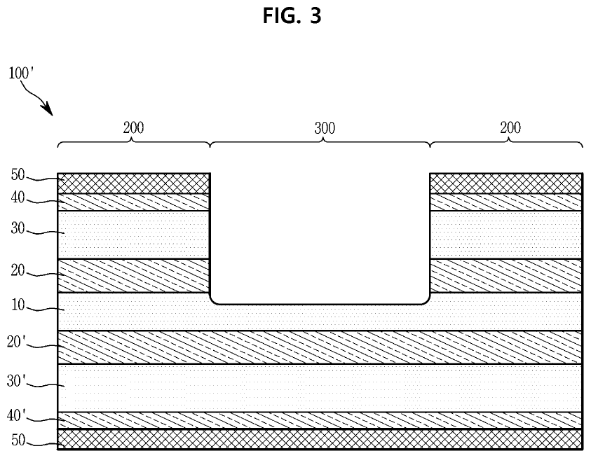

FIG. 1 is a cross-sectional view of a printed circuit board according to an embodiment of the disclosure, and FIG. 2 illustrates that the printed circuit board according to an embodiment of the disclosure is bent. FIG. 3 is a cross-sectional view of a printed circuit board according to another embodiment of the disclosure.

Referring to FIG. 1, a printed circuit board 100 according to an embodiment of the disclosure, although not shown, may be mounted on a controller of a vehicle having a high temperature and high humidity or a harsh environment in which vibration may occur, and a rigid part 200 may further extend to opposite sides of the printed circuit board 100.

The printed circuit board 100 may include the rigid part 200 configured such that a central insulating layer 10 positioned at the center of the rigid part 200 for insulation, inner copper foil layers 20 and 20′ including a conductive circuit portion, outer insulating layers 30 and 30′ for insulation, and outer copper foil layers 40 and 40′ including a conductive circuit portion, which are symmetrically positioned on opposite sides of the central insulating layer 10, are sequentially laminated.

Because the rigid part 200 may not be bent, a portion of one of opposite sides of the rigid part 200 may be removed up to one side of the central insulating layer 10 so that a flexible part 300 may be formed.

Specifically, the rigid part 200 may be configured such that the central insulating layer 10 and the outer insulating layers 30 and 30′ are provided for insulation and the inner copper foil layers 20 and 20′ and the outer copper foil layers 40 and 40′ include a conductive circuit portion, and in order to remove a portion of the rigid part 200, the rigid part 200 may be configured such that a portion of the rigid part 200 is removed by processing such as milling after laminating or may be configured such that the respective layers removed by being cut before laminating are laminated.

The flexible part 300 may be configured such that the central insulating layer 10, the inner copper foil layer 20′, the outer insulating layer 30′, and the outer copper foil layer 40′ are sequentially arranged and may be formed in 4 layers for a simple structure.

A printed circuit board according to another embodiment of the disclosure, although not shown, may be configured with 6 layers or 8 layers or more by sequentially laminating the plurality of outer insulating layers 30 and 30′ and the outer copper foil layers 40 and 40′ including a conductive circuit portion, on an outer surface of the rigid part 200.

The inner copper foil layers 20 and 20′ and the outer copper foil layers 40 and 40′ may include a copper material manufactured by electrolytic plating and rolling in order for the flexible part 300 to have flexibility, and the central insulating layer 10 and the outer insulating layers 30 and 30′ may include glass fabric and epoxy resin materials.

The flexible part 300 may be formed to have a width L of 9.5 to 10.5 mm to be able to be bent and have a thickness that does not lose reliability due to disconnection, the outer copper foil layers 40 and 40′ may be formed to have a thickness H of 18 to 35 μm, and the inner copper foil layers 20 and 20′ may be formed to have a thickness H′ of 18 to 70 μm.

As illustrated in FIG. 2, when the configuration of the printed circuit board 100 of the disclosure as described above is applied, the flexible part 300 may be bent at least 90° while having a minimum thickness without reducing the reliability due to power failure and the like even in the harsh environment inside a vehicle in which a temperature and humidity therein are high or vibration occurs.

As illustrated in FIG. 3, a printed circuit board 100′ according to another embodiment of the disclosure may further include protective layers 50 that not only may protect the outer copper foil layers 40 and 40′ by including the flexible part 300 but also may be bent on outer surfaces of the outer copper foil layers 40 and 40′.

The protective layer 50 is preferably formed of a material of a photo shoulder resist (hereinafter PSR), and when formed of the PSR, the protective layer 50 may be coated to form a protective film on the outer copper foil layers 40 and 40′, so that abnormal operation of the printed circuit due to an electrical short may be prevented.

As such, in the printed circuit boards 100 and 100′ of the disclosure as described above, a portion of the rigid part 200 having a simple laminated structure of four layers may be formed as a flexible part 300, so that a printed circuit board including the flexible part 300 capable of being bent may be provided without laminating an additional flexible layer.

Also, because the outer copper foil layers 40 and 40′ are formed to have the thickness H of 18 to 35 μm, the flexible part 300 is formed to have the minimum width L of 9.5 to 10.5 mm, and the inner copper foil layers 20 and 20′ are formed to have the thickness H′ of 18 to 7 μm, the printed circuit boards 100 and 100′ may be bent even at a thickness exceeding the above-described ranges, and even in a thin thickness less than the above-described ranges, power failure due to high humidity and vibration may be prevented.

These effects may be possible when the outer copper foil layers 40 and 40′, which are more structurally affected by a bending stress, has the thickness H that is thinner than the thickness H′ of the inner copper foil layers 20 and 20′ or is at least the same thickness because the outer copper foil layers 40 and 40′ have a larger bending radius than that of the inner copper foil layers 20 and 20′ and are made of copper and so the thinner the thickness thereof, the higher the elongation.

Also, because the flexible part 300 forms a bending curvature of 5.0R or more by having the width L of 9.5 to 10.5 mm, so that the variation in resistance of a conductor circuit may be minimized, and short circuit defects between conductors may be eliminated.

Also, in the case of forming a laminated structure of 6 or more layers according to the need of a user with the printed circuit board according to another embodiment of the disclosure, the width L of the flexible part 300 according to 4 layers may be relatively proportionally wider, so that minimal bending may be possible while power failure, etc. may be prevented.

For example, in the case of 6 layers, the flexible part 300 may preferably be formed to have the width L of 14.25 to 15.75 mm, and in the case of 8 layers, the flexible part 300 may preferably be formed to have the width L of 19 to 21 mm.

Therefore, the printed circuit board according to the disclosure is not thick due to a relatively simple laminated structure compared to a conventional laminated structure further including a separate flexible part and may be bent by the flexible part 300 having a high reliability even in an environment in a vehicle.

Also, because the protective layer 50 is coated to form a protective film on the outer copper foil layers 40 and 40′, the influence of the bending stress is insignificant, so that the flexible part 300 may be bent.

As is apparent from the above, a printed circuit board according to an embodiment of the disclosure can have a thin thickness by a relatively simple laminated structure in which a portion of a rigid part is removed to form a flexible part compared to a conventional laminated structure further including a separate flexible part, and the flexible part can be bent optimally with a high reliability without being electrically cut off even in an environment in a vehicle.

While the disclosure has been particularly described with reference to exemplary embodiments, it should be understood by those of skilled in the art that various changes in form and details may be made without departing from the spirit and scope of the disclosure.

What is claimed is:

1. A printed circuit board comprising:
a rigid part comprising a central insulating layer for insulation, inner copper foil layers including a first conductive circuit portion, outer insulating layers for insulation, and outer copper foil layers including a second conductive circuit portion, wherein ones of the inner copper foil layers, the outer insulating layers, and the outer copper foil layers are symmetrically positioned on opposite sides of the central insulating layer and are sequentially laminated; and
a flexible part formed by selectively removing a portion of the rigid part up to one side of the central insulating layer.

2. The printed circuit board according to claim 1, wherein a plurality of the outer insulating layers and the outer copper foil layers are sequentially further laminated on outer surfaces of the rigid part.

3. The printed circuit board according to claim 1, wherein the inner copper foil layers and the outer copper foil layers are manufactured by electrolytic plating and rolling with a copper material.

4. The printed circuit board according to claim 1, wherein the central insulating layer and the outer insulating layers comprise glass fabric and epoxy resin materials.

5. The printed circuit board according to claim 1, wherein the outer copper foil layers have a thickness of 18 to 35 μm.

6. The printed circuit board according to claim 1, wherein the flexible part has a width of 9.5 to 10.5 mm.

7. The printed circuit board according to claim 1, wherein the inner copper foil layers have a thickness of 18 to 70 μm.

8. The printed circuit board according to claim 1, further comprising protective layers formed on outer surfaces of the outer copper foil layers.

9. The printed circuit board according to claim 8, wherein the protective layers are formed of a photo shoulder resist (PSR).

10. A vehicle comprising:
a controller; and
a printed circuit board coupled to the controller, wherein the printed circuit board comprises:
a rigid part comprising a central insulating layer, a first inner copper foil layer over a first main surface of the central insulating layer, the first inner copper foil layer including a conductive circuit portion, a second inner copper foil layer over a second main surface of the central insulating layer, the second inner copper foil layer including a conductive circuit portion, a first outer insulating layer over the first inner copper foil layer, a second outer insulating layer over the second inner copper foil layer, a first outer copper foil layer over the first outer insulating layer, the first outer copper foil layer including a conductive circuit portion, a second outer copper foil layer over the second outer insulating layer, the second outer copper foil layer including a conductive circuit portion, wherein the first and the second inner copper foil layers, the first and the second outer insulating layers, and the first and the second outer copper foil layers are sequentially laminated; and
a flexible part formed by selectively removing a portion of the rigid part up to one side of the central insulating layer.

11. The vehicle according to claim 10, wherein additional ones of the first and the second outer insulating layers and the first and the second outer copper foil layers are sequentially further laminated on outer surfaces of the rigid part.

12. The vehicle according to claim 10, wherein the first and the second inner copper foil layers and the first and the second outer copper foil layers are manufactured by electrolytic plating and rolling with a copper material.

13. The vehicle according to claim 10, wherein the central insulating layer and the first and the second outer insulating layers comprise glass fabric and epoxy resin materials.

14. The vehicle according to claim 10, wherein:
the first and the second outer copper foil layers have a thickness of 18 to 35 μm;
the flexible part has a width of 9.5 to 10.5 mm; and
the first and the second inner copper foil layers have a thickness of 18 to 70 μm.

15. The vehicle according to claim 10, further comprising protective layers formed on outer surfaces of the first and the second outer copper foil layers.

16. The vehicle according to claim 15, wherein the protective layers are formed of a photo shoulder resist (PSR).

17. A method of making a printed circuit board, the method comprising:
laminating a first inner copper foil layer over a first main surface of a central insulating layer, the first inner copper foil layer including a conductive circuit portion;
laminating a second inner copper foil layer over a second main surface of the central insulating layer, the second inner copper foil layer including a conductive circuit portion;
laminating a first outer insulating layer over the first inner copper foil layer;
laminating a second outer insulating layer over the second inner copper foil layer;
laminating a first outer copper foil layer over the first outer insulating layer, the first outer copper foil layer including a conductive circuit portion;
laminating a second outer copper foil layer over the second outer insulating layer, the second outer copper foil layer including a conductive circuit portion; and
selectively removing portions of the first outer copper foil layer, the first outer insulating layer, the first inner copper foil layer and the central insulating layer to form a flexible part where the printed circuit board can bend, wherein portions of the printed circuit board where no layers have been removed are rigid.

18. The method according to claim 17, further comprising:
forming a first protective layer over the first outer copper foil layer; and
forming a second protective layer over the second outer copper foil layer.

19. The method according to claim 17, wherein the first and the second inner copper foil layers and the first and the second outer copper foil layers are manufactured by electrolytic plating and rolling with a copper material.

20. The method according to claim 17, wherein:
the first and the second outer copper foil layers have a thickness of 18 to 35 μm;
the flexible part has a width of 9.5 to 10.5 mm; and
the first and the second inner copper foil layers have a thickness of 18 to 70 μm.
